(19) United States
(12) Patent Application Publication
(10) Pub. No.: US 2022/0037848 A1
(43) Pub. Date: Feb. 3, 2022

(54) OPTOELECTRONIC SEMICONDUCTOR COMPONENT HAVING A REFRACTIVE INDEX MODULATION LAYER AND METHOD FOR PRODUCING THE OPTOELECTRONIC SEMICONDUCTOR COMPONENT

(71) Applicant: OSRAM Opto Semiconductors GmbH, Regensburg (DE)

(72) Inventors: Martin BEHRINGER, Regensburg (DE); Hubert HALBRITTER, Dietfurt-Toeging (DE); Matin MOHAJERANI, Regensburg (DE); Alexander BEHRES, Pfatter (DE)

(21) Appl. No.: 17/297,289

(22) PCT Filed: Nov. 29, 2019
(86) PCT No.: PCT/EP2019/083052

§ 371 Date: May 26, 2021

(30) Foreign Application Priority Data
Nov. 30, 2018 (DE) 10 2018 130 560.5

(51) Int. Cl. H01S 5/026; H01S 5/42

(52) U.S. Cl. CPC H01S 5/026; H01S 5/423

(57) ABSTRACT

An optoelectronic semiconductor component comprises a first resonator mirror, an active region suitable for generating radiation, and a second resonator mirror, which are arranged one above another in each case along a first direction. The optoelectronic semiconductor component furthermore comprises a refractive index modulation layer within an optical resonator between the first resonator mirror and the second resonator mirror. The refractive index modulation layer comprises first regions of a first material having a first refractive index and also second regions of a second material having a second refractive index, wherein the first regions are arranged directly adjacent to the second regions in a plane perpendicular to the first direction.

### CROSS-REFERENCE TO RELATED APPLICATIONS

This patent application is a national stage entry from International Application No. PCT/EP2019/083052, filed on Nov. 29, 2019, published as International Publication No. WO 2020/109534 A1 on Jun. 4, 2020, and claims priority under 35 U.S.C. § 119 from German patent application 10 2018 103 560.5, filed Nov. 30, 2018, the entire contents of all of which are incorporated by reference herein.

### BACKGROUND

In optoelectronic semiconductor components comprising an optical resonator, such as semiconductor laser devices, an emission wavelength may be set by setting the optical path length in the optical resonator, for example during production of the optoelectronic semiconductor component.

In general, concepts are being sought by means of which an emission wavelength of an optoelectronic semiconductor component may be set in a simpler manner.

The object of the present invention is to provide an improved optoelectronic semiconductor component and an improved method for producing an optoelectronic semiconductor component and an improved optoelectronic semiconductor device.

According to embodiments, the object is achieved by the subject matter and the method of the independent patent claims. Advantageous enhancements are defined in the dependent claims.

### SUMMARY

According to embodiments, an optoelectronic semiconductor component comprises a first resonator mirror, an active region suitable for generating radiation, and a second resonator mirror. The first resonator mirror, the active region and the second resonator mirror are each arranged one above the other in a first direction. The optoelectronic semiconductor component also comprises a refractive index modulation layer within an optical resonator between the first resonator mirror and the second resonator mirror. The refractive index modulation layer comprises first regions of a first material having a first refractive index and second regions of a second material having a second refractive index. The first regions are arranged directly adjacent to the second regions in a plane perpendicular to the first direction.

For example, a lateral extent of each of the first region and the second region is smaller than 0.2·λ_{eff}, λ_{eff} being an effective emission wavelength in the optical resonator. The lateral extent of each of the first region and the second region may be less than 100 nm.

The optoelectronic semiconductor component may further comprise a first layer of the first material and a second layer of the second material, the refractive index modulation layer being arranged between the first and the second layer and directly adjacent to each of the first and second layers.

The optoelectronic semiconductor component may be a surface-emitting semiconductor laser.

For example, a difference between the first refractive index and the second refractive index may be greater than 0.01, for example greater than 0.1. In general, the change in the emission wavelength due to the specific refractive index modulation layer may be all the greater, the greater the difference between the first refractive index and the second refractive index. Accordingly, the difference may be even greater than 0.5 or 0.6 or 0.8.

An optoelectronic semiconductor device contains an arrangement of a plurality of optoelectronic semiconductor components as described above. The refractive index modulation layer of at least one first and one second optoelectronic semiconductor component is each formed differently.

For example, the refractive index modulation layer of the first optoelectronic semiconductor component has a ratio of surface proportions of the first region to surface proportions of the second region different from that of the refractive index modulation layer of the second optoelectronic semiconductor component.

It is also possible for the refractive index modulation layer of the first optoelectronic semiconductor component to have a layer thickness different from that of the refractive index modulation layer of the second optoelectronic semiconductor component.

For example, the at least two semiconductor components may be controlled separately from one another.

According to embodiments, the optoelectronic semiconductor device is selected from a spectrometer or a transmitting or receiving device for several different channels.

A method for producing an optoelectronic semiconductor component comprises forming a first resonator mirror, forming an active region suitable for generating radiation, and forming a second resonator mirror. The first resonator mirror, the active region and the second resonator mirror are each arranged one above the other along a first direction. The method further includes forming a refractive index modulation layer within an optical resonator between the first resonator mirror and the second resonator mirror. The refractive index modulation layer comprises first regions of a first material having a first refractive index and second regions of a second material having a second refractive index, the first regions being arranged directly adjacent to the second regions in a plane perpendicular to the first direction.

For example, forming the refractive index modulation layer comprises forming a first layer from a first material having a first refractive index, patterning the first material so that openings are formed in a first main surface of the first layer, and depositing a second layer of a second material having a second index of refraction over the first layer. As a result, the openings in the first layer will be filled with the second material.

For example, the openings extend to a second main surface of the first layer.

According to embodiments, a lateral extent of each of the first region and the second region may be less than 0.2·λ_{eff}, λ_{eff} being an effective emission wavelength in the optical resonator.

For example, the lateral extent of each of the first region and the second region is less than 100 nm.

A difference between the first refractive index and the second refractive index may be greater than 0.01 or, in particular, greater than 0.1.

### BRIEF DESCRIPTION OF THE DRAWINGS

The accompanying drawings serve to provide an understanding of exemplary embodiments of the invention. The drawings illustrate exemplary embodiments and, together with the description, serve for explanation thereof. Further exemplary embodiments and many of the intended advantages will become apparent directly from the following detailed description. The elements and structures shown in the drawings are not necessarily shown to scale relative to each other. Like reference numerals refer to like or corresponding elements and structures.

FIG. 1 shows a schematic cross-sectional view of an optoelectronic semiconductor component according to embodiments.

FIGS. 2A and 2B illustrate a method of producing a refraction modulation layer.

FIGS. 2C and 2D each show schematic cross-sectional views of a refractive index modulation layer.

FIG. 3 shows a schematic cross-sectional view of an optoelectronic semiconductor device.

FIG. 4 shows a perspective view of an optoelectronic semiconductor device according to embodiments.

FIG. 5 outlines a method according to embodiments.

### DETAILED DESCRIPTION

In the following detailed description, reference is made to the accompanying drawings, which form a part of the disclosure and in which specific exemplary embodiments are shown for purposes of illustration. In this context, directional terminology such as “top”, “bottom”, “front”, “back”, “over”, “on”, “in front”, “behind”, “leading”, “trailing”, etc. refers to the orientation of the figures just described. As the components of the exemplary embodiments may be positioned in different orientations, the directional terminology is used by way of explanation only and is in no way intended to be limiting.

The description of the exemplary embodiments is not limiting, since there are also other exemplary embodiments, and structural or logical changes may be made without departing from the scope as defined by the patent claims. In particular, elements of the exemplary embodiments described below may be combined with elements from others of the exemplary embodiments described, unless the context indicates otherwise.

The terms “wafer” or “semiconductor substrate” used in the following description may include any semiconductor-based structure that has a semiconductor surface. Wafer and structure are to be understood to include doped and undoped semiconductors, epitaxial semiconductor layers, supported by a base, if applicable, and further semiconductor structures. For example, a layer of a first semiconductor material may be grown on a growth substrate made of a second semiconductor material or of an insulating material, for example sapphire. Depending on the intended use, the semiconductor may be based on a direct or an indirect semiconductor material. Examples of semiconductor materials particularly suitable for generating electromagnetic radiation include, without limitation, nitride semiconductor compounds, by means of which, for example, ultraviolet, blue or longer-wave light may be generated, such as GaN, InGaN, AlN, AlGaN, AlGaInN, AlGaInBN, phosphide semiconductor compounds by means of which, for example, green or longer-wave light may be generated, such as GaAsP, AlGaInP, GaP, AlGaP, and other semiconductor materials such as AlGaAs, SiC, ZnSe, GaAs, ZnO, Ga₂O₃, diamond, hexagonal BN and combinations of the materials mentioned. The stoichiometric ratio of the ternary compounds may vary. Other examples of semiconductor materials may include silicon, silicon germanium, and germanium. In the context of the present description, the term “semiconductor” also includes organic semiconductor materials.

The term “substrate” generally includes insulating, conductive or semiconductor substrates.

The terms “lateral” and “horizontal”, as used in the present description, are intended to describe an orientation or alignment which extends essentially parallel to a first surface of a semiconductor substrate or semiconductor body. This may be the surface of a wafer or a chip (die), for example.

The horizontal direction may for example lie in a plane perpendicular to a growth direction when growing layers.

The term “vertical” as used in this description is intended to describe an orientation which is essentially perpendicular to the first surface of the semiconductor substrate or semiconductor body. The vertical direction may correspond, for example, to a direction of growth when layers are grown.

To the extent used herein, the terms “have”, “include”, “comprise”, and the like are open-ended terms that indicate the presence of said elements or features, but do not exclude the presence of further elements or features. The indefinite articles and the definite articles include both the plural and the singular, unless the context clearly indicates otherwise.

In the context of this description, the term “electrically connected” means a low-ohmic electrical connection between the connected elements. The electrically connected elements need not necessarily be directly connected to one another. Further elements may be arranged between electrically connected elements.

As will be explained in the context of the present specification, the optoelectronic semiconductor component according to embodiments comprises an optical resonator which is formed between a first and a second resonator mirror. The first and the second resonator mirror may each be formed as a DBR layer stack (“distributed bragg reflector”) and comprise a plurality of alternating thin layers of different refractive indices. The thin layers may each be composed of a semiconductor material or also of a dielectric material. For example, the layers may alternately have a high refractive index (n>3.1 when using semiconductor materials, n>1.7 when using dielectric materials) and a low refractive index (n <3.1 when using semiconductor materials, n<1.7 when using dielectric materials). For example, the layer thickness may be λ/4 or a multiple of λ/4, wherein λ is the wavelength of the light to be reflected in the respective medium. The first or the second resonator mirror may comprise 2 to 50 individual layers, for example. A typical layer thickness of the individual layers may be about 30 to 150 nm, for example 50 nm. The layer stack may furthermore contain one or two or more layers that are thicker than about 180 nm, for example thicker than 200 nm.

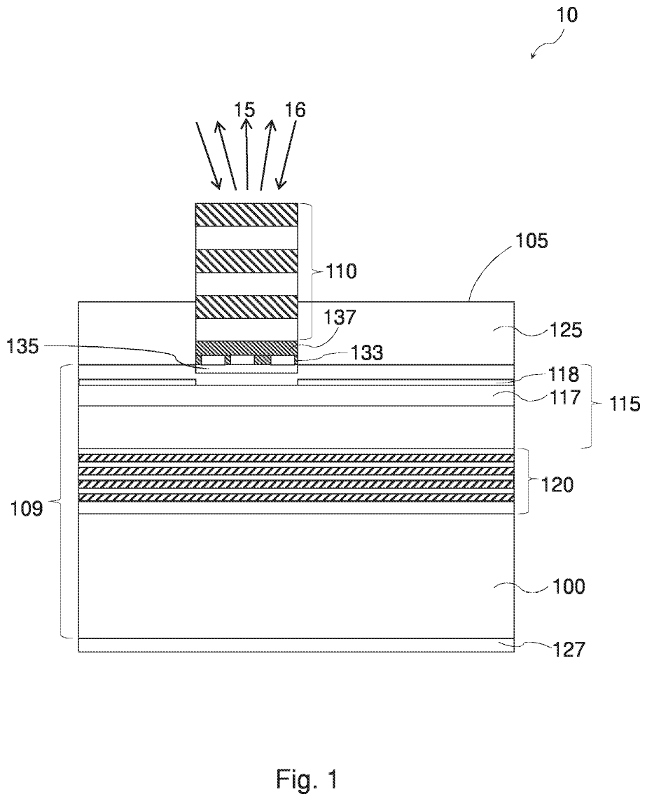

FIG. 1 shows a schematic cross-sectional view of an optoelectronic semiconductor component 10 according to embodiments. The optoelectronic semiconductor component 10 comprises a first resonator mirror 110, an active region 115 suitable for generating radiation, and a second resonator mirror 120. The first resonator mirror, the active region and the second resonator mirror are each arranged one above the other along a first direction. The optoelectronic semiconductor component also comprises a refractive index modulation layer within an optical resonator between the first resonator mirror 110 and the second resonator mirror 120. The refractive index modulation layer 133 comprises first regions 136 of a first material having a first refractive index and second regions 138 of a second material having a second refractive index. The first regions 136 are arranged directly adjacent to the second regions 138 in a plane perpendicular to the first direction.

The first and the second resonator mirrors 110, 120 may each comprise alternately stacked first layers of a first composition and second layers of a second composition. For example, the second resonator mirror 120 may have an overall reflectivity of 99.8% or more for the electromagnetic radiation generated. It is noted that, in the depiction of the first and second resonator mirrors 110, 120 in FIG. 1, they may not be true to scale. For example, the first resonator mirror 110 and the refractive index modulation layer are shown enlarged in order to better illustrate properties of the refractive index modulation layer 133 in particular.

For example, the active region 115 may be based on a nitride, a phosphide or an arsenide compound semiconductor material. The active region 115 may, for example, include doped semiconductor layers, for example a first doped semiconductor layer of a first conductivity type, for example p-type. The active region 115 may furthermore include a second doped semiconductor layer of a second conductivity type, for example n-type. For example, these layers may be jacket or cladding layers. The active region 115 may furthermore comprise an active zone 117. The active zone 117 may, for example, comprise a pn junction, a double heterostructure, a single quantum well structure (SQW, single quantum well) or a multiple quantum well structure (MQW, multi quantum well) for generating radiation. The term “quantum well structure” does not imply any particular meaning here with regard to the dimensionality of the quantization. Therefore it includes, among other things, quantum wells, quantum wires and quantum dots as well as any combination of these layers.

The optoelectronic semiconductor component may be formed in a semiconductor body 109, for example. The semiconductor body 109 may, for example, include a substrate 100, the second resonator mirror 120 and the active region 115. For example, the substrate 100 may contain GaN, GaP or GaAs or silicon. The further layers of the semiconductor body may contain, for example, nitride, phosphide or arsenide semiconductor materials. The semiconductor body 109 may, for example, include layers of the composition AlₓGa_{y}In_{1-x-y}As with 0≤x, y≤1. According to further embodiments, the semiconductor body 109 may also be based on the InGaAlP material system and comprise semiconductor layers of the composition InₓGa_{y}Al_{1-x-y}P_{z}As_{1-z} with 0≤x, y, z≤1. The layers of the semiconductor body 109 may be formed epitaxially, for example.

For example, the second resonator mirror 120 is arranged between the active region 115 and the substrate 100. The first resonator mirror 110 and the second resonator mirror 120 form an optical resonator for the electromagnetic radiation 20 generated in the active region 115. The first resonator mirror 110 may, for example, be composed of dielectric layers. The first resonator mirror 110 may be formed as an outcoupling mirror for the laser radiation generated in the resonator by means of induced emission and has, for example, a lower reflectivity than the second resonator mirror 120. Electromagnetic radiation 15 generated in active region 115 is emitted from the optoelectronic component in the vertical direction, for example. The emission may in particular take place in a direction which intersects a first main surface 105 of the optoelectronic semiconductor component. The first main surface 105 of the optoelectronic semiconductor component is perpendicular to the first direction, i.e. the arrangement direction of the first and second resonator mirrors

According to embodiments, as described above, the optoelectronic semiconductor component may be a semiconductor laser device, in particular a surface-emitting semiconductor laser (“vertical cavity surface emitting laser”, VCSEL). According to further embodiments, the optoelectronic semiconductor component may also be a conventional LED or a light-receiving element. For example, the optoelectronic semiconductor component 10 may form a detector.

According to embodiments, a first contact element 125 may be arranged in the region of the first main surface 105 of the optoelectronic semiconductor component. For example, a surface of the first contact element 125 may form a first main surface of the optoelectronic semiconductor component 10. A second contact element 127 may be directly adjacent to a second main surface of the substrate 100. The first contact element 125 and the second contact element 127 are electrically connected to the active region 115. For example, the first contact element 125 may be connected to a first cladding layer, for example of a first conductivity type. The second contact element 127 may be connected to a second cladding layer, for example of a second conductivity type.

The optoelectronic semiconductor component 10 represents a semiconductor laser, for example, which may be electrically pumped via the first contact element 125 and the second contact element 127, for example. For example, at least one layer of the second resonator mirror 120 may be doped with dopants of a second conductivity type, for example n-type. The semiconductor layer directly adjacent to the first contact element 125 may be doped with dopants of the first conductivity type, for example p-type. The substrate 100 may also be doped, for example with dopants of the second conductivity type. According to further embodiments, the second resonator mirror 120 may be composed of the electrical layers. The optoelectronic semiconductor component 10 may comprise further components which are useful or necessary for the operation of a (surface-emitting) semiconductor laser device. For example, a current confinement layer 118 may be provided, which has the effect that the current flows exclusively in the region in which the laser radiation is generated. For example, the current confinement layer 118 may be electrically insulating. The layer 118 for current confinement may be interrupted in a region which is arranged between the resonator mirrors and overlaps the resonator mirrors. For example, the current confinement layer 118 may be arranged directly adjacent to the active zone 117. According to embodiments, the current confinement layer 118 may be a layer with a high aluminum content, which is locally oxidized and is insulating at the oxidized points. According to further embodiments, the current confinement layer 118 may also be omitted or implemented in an alternative manner. Current confinement may also be achieved in other ways, if necessary.

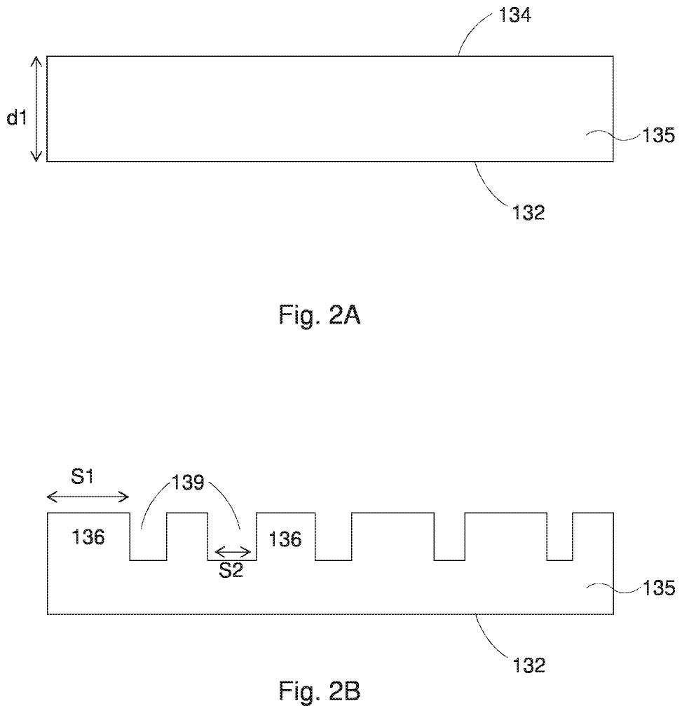

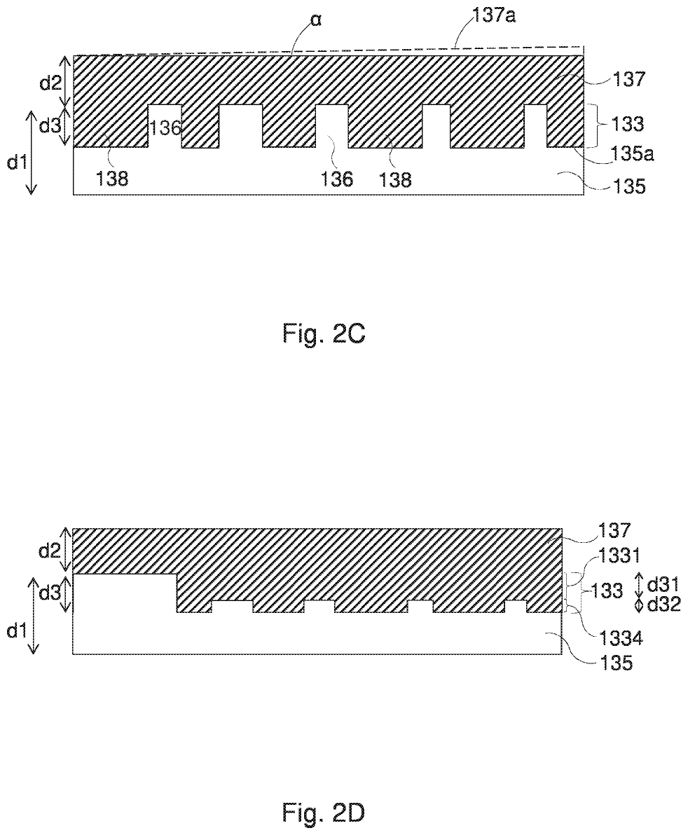

The refractive index modulation layer 133 will be described in greater detail with reference to FIGS. 2C and 2D. According to embodiments, a first dielectric layer 135 of the first material having the first refractive index and a second dielectric layer 137 made of the second material having the second refractive index may be directly adjacent to the refractive index modulation layer 133. Furthermore, according to embodiments, the first resonator mirror 110 may be directly adjacent to the refractive index modulation layer 133 or the second dielectric layer 137 of the second refractive index. According to further embodiments, however, further layers may also be arranged between the refractive index modulation layer 133 and the first resonator mirror 110. According to further embodiments, the refractive index modulation layer 133 may be arranged directly adjacent to the second resonator mirror 120.

As has been described, the refractive index modulation layer 133 comprises first regions 136 of a first material having a first refractive index and second regions 138 of a second material having a second refractive index, the first regions 136 being directly adjacent to the second Regions 138 in a plane perpendicular to the first direction.

This refractive index modulation layer 133 may be formed as follows. First, as shown in FIG. 2A, a first dielectric layer 135 is formed with a layer thickness d₁. The first dielectric layer 135 is then patterned, for example using photolithographic methods. For example, a photomask is produced and openings 139 are produced in a first main surface 134 of the first dielectric layer 135, for example by etching. The first dielectric layer 135 is patterned, for example, in such a way that a maximum horizontal dimension s₂ of the openings 139 is less than 0.2·λ_{eff}, λ_{eff} being an effective emission wavelength in the optical resonator. Furthermore, according to embodiments, a maximum distance s₁ between adjacent openings 139 is less than 0.2·λ_{eff}. For example, s₁ and s₂ are each smaller than 100 nm. The etching is carried out to a predetermined depth. According to embodiments, the etching may also be carried out to a second main surface of the first electrical layer 135. As a result, first regions 136 of the first dielectric material are obtained, which are separated by the openings 139, as also shown in FIG. 2B.

Then a second dielectric layer 137 of a second dielectric material having a second refractive index is formed. As a result, the second dielectric material fills the openings 139. The second layer 137 is then planarized, for example, e.g. by means of a CMP (“chemical-mechanical polishing”) method. As a result, the structure shown in FIG. 2C is obtained.

FIG. 2C shows an enlarged schematic cross-sectional view of the refractive index modulation layer 133 and optionally the adjacent first and second dielectric layers 135, 137.

This results in an effective refractive index n₃ of the refractive index modulation layer 133 as a function of the surface proportions which are occupied by the first regions 136 and the second regions 138, respectively, as follows:

n₃=(n₁·A₁+n₂·A₂)/(A₁+A₂)

A₁ denotes the sum of all regions 136 occupied by the first material. A₂ denotes the sum of all regions 138 occupied by the second material. Accordingly, the optical path length in the refractive index modulation layer 133 changes to n₃·d₃.

In this way, the optical path length between the first and the second resonator mirrors 110, 120 may be changed by varying the surface proportions of the first regions 136 and the second regions 138. In this way, the emission wavelength in the optical resonator may be set in a selective manner by means of the different patterning of the refractive index modulation layer 133. Possible material combinations of the first and second dielectric layers include, for example, SiO, TiO, NbO and SiN. For example, the materials of the first and second dielectric layers may be selected such that the difference in the refractive indices is as large as possible, for example greater than 0.5 or 0.6 or 0.8.

In comparison to a layer structure comprising a first dielectric layer 135 having a layer thickness d1 and a first refractive index n1 and a second dielectric layer 137 having a layer thickness d2 and a second refractive index n2, the optical path length changes as follows:

λ1=n₃·d₃−n₁·d₃

Here, d3 corresponds to the layer thickness of the refractive index modulation layer 133 and may, for example, be equivalent to the etching depth. According to embodiments, it is not absolutely necessary to exactly adhere to the etching depth d3. According to embodiments, acalibration may also take place after the refraction index modulation layer 133 has been produced.

As has been described, a first dielectric layer 135 may first be applied and then patterned, only part of the first layer 135 being etched away and filled with the material of the second layer 137. According to further embodiments, the first layer 135 may be etched through completely during patterning, so that, as a result, only the refractive index modulation layer 133 and, if applicable, the second dielectric layer 137 is present. Optionally, the second dielectric layer 137, too, may be removed from the regions outside the refractive index modulation layer 133. A first main surface 137a of the second dielectric layer 137 does not necessarily need to be parallel to a first main surface 135a of remaining parts of the first layer 135. For example, the first main surface 137a may be slightly inclined with respect to the first main surface 135a of the first layer 135. An angle α between the first main surface 137a and the first main surface 135 may, for example, be at most 5°. Furthermore, the first main surface 137a need not be exactly horizontal, but may rather be slightly shaped, for example to form a lens. In this case, an angle α between the first main surface 137a of the second dielectric layer 137 and the first main surface 135a of the first layer 135 may be less than 5°.

Furthermore, a first main surface 137a of the second dielectric layer 137 may be polished, for example by a polishing method, in such a way that it is very smooth. According to further embodiments, the first main surface 137a may also be rough.

According to further embodiments, as shown in FIG. 2D, the first dielectric layer 135 may be patterned, so that regions of different layer thicknesses d21, d22 are present. For example, openings in the first dielectric layer 135 may be etched in a first photolithographic process, which extend to a first depth. In a second process, openings are etched in the first dielectric layer 135 that extend to a second depth. As a result, the structure shown in FIG. 2D may be obtained after the second dielectric layer 137 is formed. The refractive index n3 is produced in the various sub-layers taking into account the respective surface coverage levels. When determining the effective resonator length, the respective layer thicknesses d₃₁ and d₃₂ of the respective sub-layers are taken into account. As a result, various different refractive indices may be set for the refractive index modulation layer 133.

According to embodiments, a greater difference in the resonator length and thus in the emitted wavelength may be achieved by means of a particularly large difference in the refractive indices of the first layer 135 and the second layer 137 or by means of a greater etching depth. For example, at an etching depth of 35 nm, at a refractive index difference of 0.5 between the layers 135, 137, at an emission wavelength of about 848 nm and, for example, by means of a short resonator having a length in the order of an effective wavelength, a wavelength shift of the resonance frequency of about 0.8 nm may be achieved towards higher wavelengths.

The method described enables the emission wavelength of a semiconductor laser to be set to a desired value in a simple manner. In contrast to conventional methods, in which the resonator mirror must be set to a specific position, such setting may be done here by simple processes of patterning a dielectric layer.

According to embodiments, an optoelectronic semiconductor device may comprise a plurality of above-described optoelectronic semiconductor components. For example, at least two of the optoelectronic semiconductor components may have a different ratio of surface proportions of the first region and surface proportions of the second region. According to further embodiments, a layer thickness of the refractive index modulation layer may also vary. Accordingly, there is a different effective resonator length in each case. As a result, the optoelectronic semiconductor components are able to each emit different wavelengths.

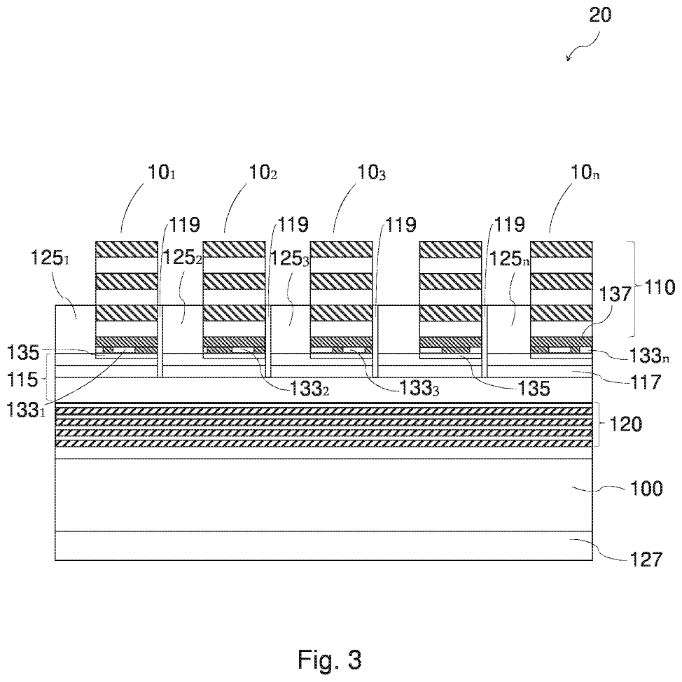

FIG. 3 shows a schematic cross-sectional view of an optoelectronic semiconductor device comprising an arrangement of several optoelectronic semiconductor components. The optoelectronic semiconductor device 20 comprises several optoelectronic semiconductor components 10₁, 10₂, . . . , 10ₙ. The various optoelectronic semiconductor components are integrated, for example, on a common substrate 100 and comprise, for example, a common second resonator mirror 120 and a common active region 115. Furthermore, the various optoelectronic semiconductor components 10₁, 10₂, . . . , 10ₙ may be electrically connectable via a common second contact element 127. Each of the optoelectronic semiconductor components 10₁, 10₂, . . . , 10ₙ comprises its own first resonator mirror 110. Furthermore, each of the individual optoelectronic semiconductor components comprises a separate refractive index modulation layer 133₁, 133₂, . . . , 133ₙ. Each of these refractive index modulation layers 133₁, 133₂, . . . , 133ₙ may comprise a different effective refractive index and therefore a different path length shift. According to further embodiments, the layer thickness of the refractive index modulation layers may also be different in each case.

For example, in the case of the optoelectronic semiconductor device shown in FIG. 3, an emission wavelength of the optoelectronic semiconductor device may be set by targeted and selective control of an optoelectronic semiconductor component 10₁, 10₂, . . . , 10ₙ via the associated contact element 125. The current through the contact element 125i should only flow through the associated optoelectronic semiconductor component(s) 10i. This may be achieved, for example, by providing separating elements 119 which are implemented, for example, as trenches that are filled with an insulating material. The separating elements 119 prevent the current from flowing to neighboring optoelectronic semiconductor components. The separating elements 119 extend, for example, through the active zone 117. The separating elements 119 may also be embodied in other ways.

According to embodiments, groups of optoelectronic semiconductor components which each emit at the same wavelength may also be controlled each by one contact element 125i. For example, identical optoelectronic semiconductor components may be arranged in blocks or as strips. Furthermore, such groups may be controlled in a targeted and selective manner, so that in each case an emission wavelength of the optoelectronic semiconductor device may be set.

In this way, by using only one photolithographic process, an optoelectronic semiconductor device may be implemented in which the emission wavelength is adjustable. According to embodiments, single semiconductor components 10₁, 10₂, . . . , 10ₙ may each be controlled individually. According to further embodiments, it is also possible to control groups of semiconductor components which, for example, each comprise identical refractive index modulation layers.

The optoelectronic semiconductor device may, for example, be a light source for a spectrometer or a multi-channel chip that may be used, for example, for communications engineering applications. According to further embodiments, the spectrometer may be used to examine food at different wavelengths in each case. This, for example, allows for the presence and concentration of different ingredients to be determined. According to further embodiments, the optoelectronic semiconductor device may also be a detector which detects different wavelengths.

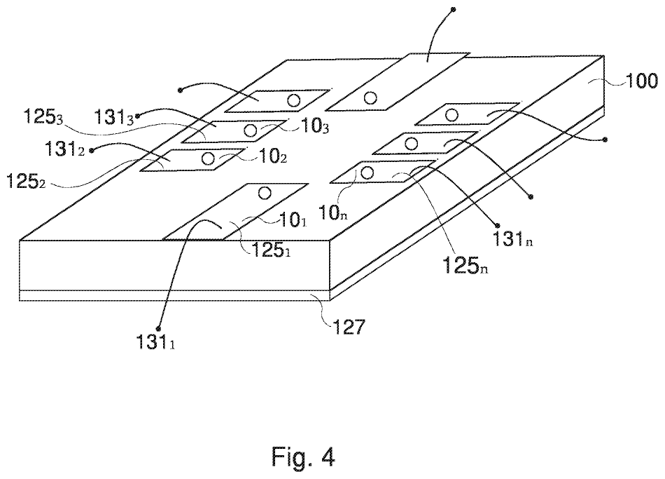

FIG. 4 shows a perspective view of an optoelectronic semiconductor device according to embodiments. The plurality of optoelectronic semiconductor components 10₁, 10₂, . . . , 10ₙ is integrated into a common semiconductor substrate 100 and connected to a second electrical contact element 127, for example. Different first contact elements 125₁, 125₂, . . . , 125ₙ may each be connected to respective separate electrical connections 131₁, 131₂, . . . , 131ₙ. According to further embodiments, the individual optoelectronic semiconductor components may also be arranged in rows and columns and may be connected by applying respective voltages to lines which each extend along a row and a column.

Due to the simple structure, optoelectronic semiconductor devices may be produced much more easily and with greater packing density. Furthermore, by providing a refractive index modulation layer, it is possible to compensate for a systematic variation in the emission wavelength from center to edge within a wafer. Furthermore, by providing a refractive index modulation layer, a variation in the layer thickness of the layers that make up the optical resonator may be compensated for.

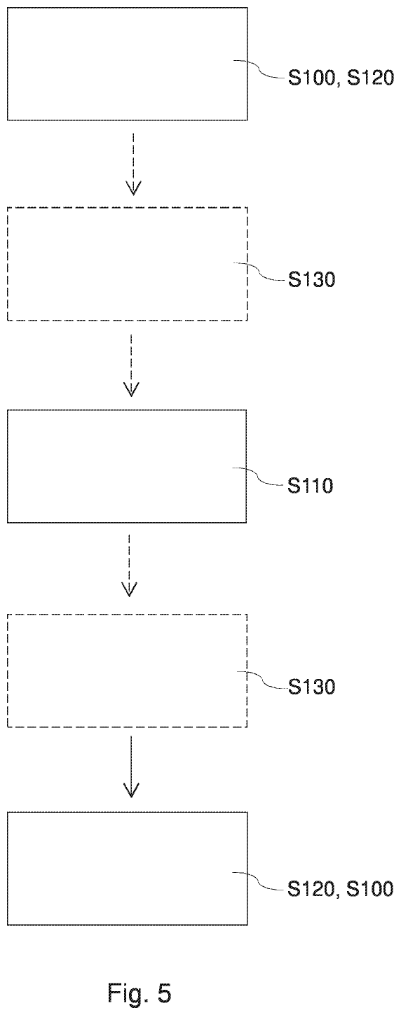

FIG. 5 outlines a method according to embodiments. A method for producing an optoelectronic semiconductor component comprises forming (S100) a first resonator mirror, forming (S110) an active region suitable for generating radiation, and forming (S120) a second resonator mirror, wherein the first resonator mirror, the active region and the second resonator mirrors are each arranged one above the other along a first direction. The method further comprises forming (S130) a refractive index modulation layer within an optical resonator between the first resonator mirror and the second resonator mirror. The refractive index modulation layer comprises first regions of a first material having a first refractive index and second regions of a second material having a second refractive index, the first regions being arranged directly adjacent to the second regions in a plane perpendicular to the first direction. For example, the first resonator mirror may be formed prior to the second resonator mirror. Alternatively, the second resonator mirror may be formed prior to the first resonator mirror. The refractive index modulation layer is formed such that it is arranged within the optical resonator. The refractive index modulation layer may be formed prior to or after forming the active region.

Although specific embodiments have been illustrated and described herein, those skilled in the art will recognize that the specific embodiments shown and described may be replaced by a multiplicity of alternative and/or equivalent configurations without departing from the scope of the invention. The application is intended to cover any adaptations or variations of the specific embodiments discussed herein. Therefore, the invention is to be limited by the claims and their equivalents only.

1. An optoelectronic semiconductor component comprising:
a first resonator mirror,
an active region configured to generate radiation,
a second resonator mirror,
which are each arranged one above the other along a first direction, and
a refractive index modulation layer within an optical resonator between the first resonator mirror and the second resonator mirror, wherein the refractive index modulation layer comprises first regions of a first material having a first refractive index and second regions of a second material having a second refractive index, the first regions being arranged directly adjacent to the second regions in a plane perpendicular to the first direction, and wherein at least one of the first regions has a height which is different from the height of further first regions, the height being measured along the first direction, further comprising
a first layer of the first material and a second layer of the second material, wherein the refractive index modulation layer is arranged between the first and the second layers and is directly adjacent to the first and the second layers, respectively.

2. The optoelectronic semiconductor component according to claim 1, wherein a lateral extent of each of the first region and of the second region is less than 0.2·λ_{eff}, λ_{eff} being an effective emission wavelength in the optical resonator.

3. The optoelectronic semiconductor component according to claim 2, wherein the lateral extent of each of the first region and of the second region is less than 100 nm.

4. The optoelectronic semiconductor component according to claim 1, wherein a first main surface of the second layer is inclined or curved with respect to a first main surface of the first layer.

5. The optoelectronic semiconductor component according to claim 4, wherein an angle a between the first main surface of the second layer and the first main surface of the first layer is less than 5°.

6. The optoelectronic semiconductor component according to claim 1, wherein the optoelectronic semiconductor component is a surface-emitting semiconductor laser.

7. The optoelectronic semiconductor component according to claim 1, wherein a difference between the first refractive index and the second refractive index is greater than 0.1.

8. An optoelectronic semiconductor device comprising an array of a plurality of optoelectronic semiconductor components according to claim 1, wherein the refractive index modulation layer of at least one first and one second optoelectronic semiconductor component is each formed differently.

9. The optoelectronic semiconductor device according to claim 8, wherein the refractive index modulation layer of the first optoelectronic semiconductor component has a ratio of surface proportions of the first region to surface proportions of the second region different from that of the refractive index modulation layer of the second optoelectronic semiconductor component.

10. The optoelectronic semiconductor device according to claim 8, wherein the at least two semiconductor components are configured to be controlled separately from one another.

11. The optoelectronic semiconductor device according to claim 8, which is selected from a light source for a spectrometer or a transmitting or receiving device for several different channels.

12. A method for producing an optoelectronic semiconductor component comprising:
forming a first resonator mirror,
forming an active region suitable for generating radiation,
forming a second resonator mirror, wherein the first resonator mirror, the active region and the second resonator mirror are each arranged one above the other along a first direction, and
forming a refractive index modulation layer within an optical resonator between the first resonator mirror and the second resonator mirror, the refractive index modulation layer comprising first regions of a first material having a first refractive index and second regions of a second material having a second refractive index, wherein the first regions are arranged directly adjacent to the second regions in in a plane perpendicular to the first direction, in which forming the refractive index modulation layer comprises:
forming a first layer of the first material having the first refractive index,
patterning the first material so that openings are formed in a first main surface of the first layer, wherein at least two of the openings extend to a different depth, and
depositing a second layer of the second material having the second refractive index of refraction over the first layer, so that the openings in the first layer are filled with the second material.

13. The method according to claim 12, wherein a lateral extent of each of the first region and of the second region is less than 0.2·λ_{eff}, λ_{eff} being an effective emission wavelength in the optical resonator.

14. The method according to claim 13, wherein the lateral extent of each of the first region and of the second region is less than 100 nm.

15. The method according to claim 12, wherein a difference between the first refractive index and the second refractive index is greater than 0.01.
